(19) United States
(12) Patent Application Publication
(10) Pub. No.: US 2026/0221990 A1
(43) Pub. Date: Jul. 30, 2026

(54) CODING METHOD AND DECODING METHOD, CODER AND DECODER, AND CHIP, HARD DISK, AND COMMUNICATION SYSTEM

(71) Applicant: CLOUD INTELLIGENCE ASSETS HOLDING (SINGAPORE) PRIVATE LIMITED, Singapore (SG)

(72) Inventor: Shu LI, Sunnyvale, CA (US)

(21) Appl. No.: 19/147,668

(22) PCT Filed: Jan. 10, 2024
(86) PCT No.: PCT/CN2024/071647

§ 371 Date: Jul. 11, 2025

(30) Foreign Application Priority Data
Jan. 11, 2023 (CN) 202310063826.1

(51) Int. Cl. H03M 13/00; H03M 13/05; H04L 1/00

(52) U.S. Cl. CPC H03M 13/6505; H03M 13/05; H04L 1/0041; H04L 1/0045; H04L 1/0057

(57) ABSTRACT

Embodiments of this application provide a coding method and a decoding method, a coder, a decoder, a chip, a hard disk, and a communication system. An error correcting encoding method, including: obtaining target data, where the target data is data obtained by performing data alignment on raw data and then performing data compression; determining, from a plurality of error correcting codes based on a data length of the target data, at least one error correcting code corresponding to the target data, where at least some of the error correcting codes have different lengths; and performing error correcting encoding on the target data based on the at least one error correcting code corresponding to the target data, to obtain at least one error correcting codeword.

### CROSS-REFERENCE TO RELATED APPLICATIONS

This application is a National Stage of International Application No. PCT/CN2024/071647, filed on Jan. 10, 2024, which claims priority to Chinese Patent Application No. 202310063826.1, filed with the China National Intellectual Property Administration on Jan. 11, 2023 and entitled “CODING METHOD AND DECODING METHOD, CODER AND DECODER, AND CHIP, HARD DISK, AND COMMUNICATION SYSTEM”. These applications are incorporated herein by reference in their entireties.

### TECHNICAL FIELD

Embodiments of this application relate to the field of data processing technologies, and in particular, to a coding method and a decoding method, a coder and a decoder, a chip, a hard disk, and a communication system.

### BACKGROUND

An error correcting code (ECC) is an important means for ensuring data validity, and is often used in fields such as data transmission and data storage. Using the field of data storage as an example, generally, data alignment (for example, 4k alignment) is performed on a data block and then data compression is performed, and unpredictability of data content leads to different lengths of compressed data. The error correcting code aims at data having a fixed length. Therefore, data having different lengths need to be spliced, to obtain data whose length meets a requirement of the error correcting code, and then the data is encoded by using the error correcting code, to obtain an error correcting codeword.

However, splicing the data having different lengths to obtain the data whose length meets the requirement of the error correcting code may cause a piece of data to be located in two different error correcting codewords. This may cause read amplification and increase complexity of a data obtaining process.

In view of this, a technical problem that needs to be resolved urgently in an existing technology is how to reduce read amplification caused by data splicing in an error correcting encoding process.

### SUMMARY

In view of this, embodiments of this application provide a coding or decoding solution, to at least partially resolve the foregoing problem.

According to a first aspect of embodiments of this application, an error correcting encoding method is provided. The method includes: obtaining target data, where the target data is data obtained by performing data alignment on raw data and then performing data compression; determining, from a plurality of error correcting codes based on a data length of the target data, at least one error correcting code corresponding to the target data, where at least some of the error correcting codes have different lengths; and performing error correcting encoding on the target data based on the at least one error correcting code corresponding to the target data, to obtain at least one error correcting codeword.

According to a second aspect of embodiments of this application, a coder is provided. The coder includes: a data obtaining module and an error correcting coder. The data obtaining module is configured to obtain target data, and determine, from a plurality of error correcting codes based on a data length of the target data, at least one error correcting code corresponding to the target data. The target data is data obtained by performing data alignment on raw data and then performing data compression, and at least some of the error correcting codes have different lengths. The error correcting coder is configured to perform error correcting encoding on the target data based on the at least one error correcting code corresponding to the target data, to obtain at least one error correcting codeword.

According to a third aspect of embodiments of this application, an error correcting decoding method is provided. The method includes: obtaining at least one error correcting codeword; determining, from a plurality of error correcting codes based on a length of the error correcting codeword, an error correcting code corresponding to the error correcting codeword, where at least some of the error correcting codes have different lengths; and decoding the error correcting codeword based on the error correcting code, to obtain decoded data.

According to a fourth aspect of embodiments of this application, a decoder is provided. The decoder includes: a codeword obtaining module, configured to obtain at least one error correcting codeword; and an error correcting decoder, configured to determine, from a plurality of error correcting codes based on a length of the error correcting codeword, an error correcting code corresponding to the error correcting codeword, and decode the error correcting codeword based on the error correcting code, to obtain decoded data, where at least some of the error correcting codes have different lengths.

According to a fifth aspect of embodiments of this application, a storage control chip is provided. The chip includes: the foregoing coder or the foregoing decoder.

According to a sixth aspect of embodiments of this application, a solid state disk is provided. The solid state disk includes: the foregoing storage control chip; and at least one flash memory chip, where the flash memory chip includes at least one memory block, each memory block includes a plurality of memory pages, and each memory page includes a plurality of storage units.

According to a seventh aspect of embodiments of this application, a communication system is provided. The system includes a transmit end and a receive end. The transmit end includes the foregoing coder, and the receive end includes the foregoing decoder.

According to a check code generation solution provided in embodiments of this application, the plurality of error correcting codes are set, at least some of the error correcting codes having different lengths, and the at least one error correcting code corresponding to the target data is determined from the plurality of error correcting codes based on the data length of the target data, to flexibly encode the target data. This is applicable to a data block having an indefinite data length, to avoid operations such as head-to-tail connection and segmentation, so as to implement independent error correcting code protection of each piece of compressed target data, isolate crosstalk between different target data blocks, reduce read amplification, facilitate metadata management, facilitate data recovery, and timely release storage space.

### BRIEF DESCRIPTION OF DRAWINGS

To describe the technical solutions in embodiments of this application or in the conventional technology more clearly, the following briefly describes the accompanying drawings required for describing embodiments or the conventional technology. Apparently, the accompanying drawings in the following description are merely some of embodiments of this application, and a person of ordinary skill in the art may still derive other drawings from these accompanying drawings.

FIG. 1 is a schematic block diagram of a solid state disk.

FIG. 2 is a schematic diagram of an existing data error correcting encoding method.

FIG. 3 is a flowchart of steps of an error correcting encoding method according to an embodiment of this application.

FIG. 4 is a schematic diagram of a plurality of error correcting codes according to an embodiment of this application.

FIG. 5 is a schematic diagram of matching target data with an error correcting code according to an embodiment of this application.

FIG. 6 is another schematic diagram of matching target data with an error correcting code according to an embodiment of this application.

FIG. 7 is a block diagram of a structure of a coder according to an embodiment of this application.

FIG. 8 is a block diagram of a structure of another coder according to an embodiment of this application.

FIG. 9 is a flowchart of steps of an error correcting decoding method according to an embodiment of this application.

FIG. 10 is a block diagram of a structure of a decoder according to an embodiment of this application.

FIG. 11 is a block diagram of a structure of another decoder according to an embodiment of this application.

FIG. 12 is a schematic diagram of a structure of a communication system according to an embodiment of this application.

### DESCRIPTION OF EMBODIMENTS

To enable a person skilled in the art to better understand the technical solutions in embodiments of this application, the following clearly and completely describes the technical solutions of embodiments of this application with reference to the accompanying drawings in embodiments of this application. Apparently, the described embodiments are merely some rather than all of embodiments of this application. All other embodiments obtained by a person of ordinary skill in the art based on embodiments in embodiments of this application should fall within the protection scope of embodiments of this application.

The following describes in detail specific implementation of embodiments of this application with reference to the accompanying drawings in embodiments of this application.

First, some terms used in the description of embodiments of this application are explained below.

NAND flash memory: The NAND flash memory is also referred to as a NAND (NOT-AND) flash memory, and is a non-volatile flash memory. The NAND flash memory uses tunneling injection for writing and tunneling release for erasing. Address lines and data lines are multiplexed. Tunneling injection for writing is a process of writing data into storage by injecting electrons through a tunneling effect of quantum mechanics, and electron tunneling release caused by a voltage is a process of clearing data stored in the storage.

Storage unit: The storage unit is an element constituting a NAND flash memory. The NAND flash memory includes a plurality of memory blocks, and each memory block includes a plurality of memory pages.

### Solid State Disk

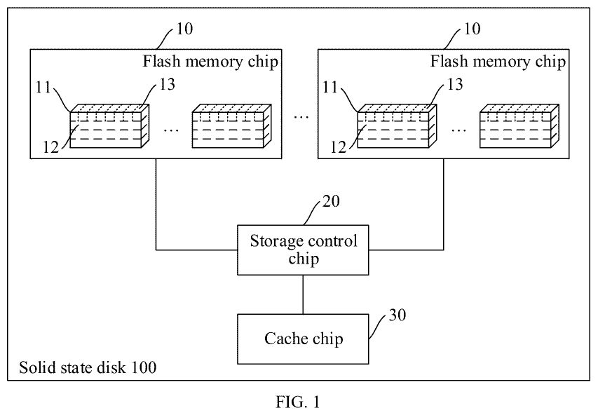

FIG. 1 is a schematic block diagram of a solid state disk 100. The solid state disk (Solid State Disk or Solid State Drive, SSD) is also referred to as a solid state drive, and is a hard disk drive made of an array of solid-state electronic storage chips. Based on different storage media, the solid state disk may be classified into a flash memory (flash)-based solid state disk and a dynamic random access memory (DRAM)-based solid state disk. The solid state disk 100 in this embodiment of this application is a NAND flash memory-based solid state disk.

Compared with a conventional mechanical hard disk drive, the solid state disk has many advantages, and a largest advantage thereof is security of stored data. For example, when the solid state disk is shaken during use, there is no need to worry about damaging the stored data, and a sudden power loss during use does not cause data loss in the solid state disk. Based on this, the solid state disk is widely used in various complex working environments, such as a highly available server, and is also an ideal storage device for a personal user.

As shown in FIG. 1, the solid state disk 100 may include a plurality of flash memory chips 10. Each flash memory chip 10 may include a plurality of memory blocks 11, and each memory block 11 may include a plurality of memory pages 12. Data in the solid state disk 100 is stored in a storage unit 13 in the flash memory chip 10. For example, the flash memory chip 10 includes 1024 memory blocks 11, each memory block 11 includes 64 memory pages 12, and each memory page 12 includes 217 storage units 13. Each storage unit 13 may store data of 1 bit, that is, each storage unit 13 may store a binary number 0 or 1. In this embodiment of this application, the flash memory chip 10 is a NAND flash memory.

In addition to the flash memory chip 10 configured to store data, the solid state disk 100 may further include a storage control chip 20 and a cache chip 30.

The storage control chip 20 is configured to control a read/write operation of the solid state disk, and a corresponding software program is written into the storage control chip 20.

Specifically, the storage control chip 20 may include a coder and/or a decoder.

During data writing, the coder in the storage control chip may perform data alignment on data and then perform compression, then segment and splice compressed data to enable a data length to be a length corresponding to an error correcting code, and send the data to the coder. The coder may perform error correcting encoding on data having a fixed length to obtain an error correcting codeword, and store the error correcting codeword into the memory page 12.

During data reading, the decoder in the storage control chip may read data from the memory page 12, and input the data to the decoder. Error correcting decoding is performed by using the decoder, to obtain decoded data.

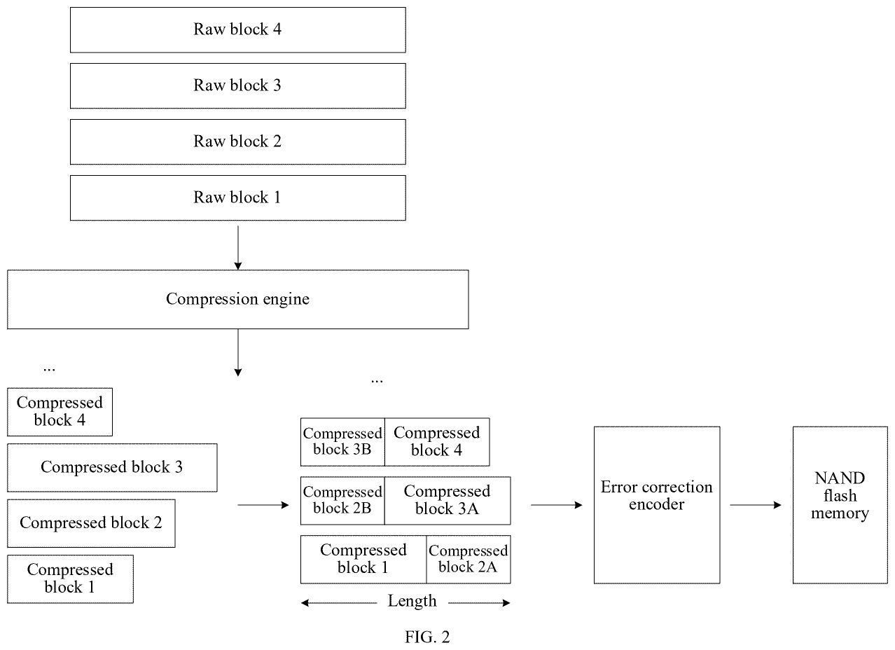

However, refer to FIG. 2. During data writing, generally, data is aligned and compressed first. FIG. 2 shows four pieces of data aligned into a fixed size.

The aligned data may be input to a compression engine for data compression. As a type of the data is unpredictable, a length of compressed data is unpredictable. For example, refer to FIG. 2. Four compressed blocks 1, 2, 3, and 4 obtained by compressing four data-aligned raw blocks 1, 2, 3, and 4 have different lengths.

During data writing, the four compressed blocks need to be connected head to tail to reach a specific length, and then are segmented based on an coding length of an error correcting code, to obtain data whose data length meets a requirement of the error correcting code, specifically, for example, three pieces of data “compressed block 1+compressed block 2A”, “compressed block 2B+compressed block 3A”, and “compressed block 3B+compressed block 4” shown in FIG. 2. Error correcting encoding is performed on the three pieces of data by using an error correcting coder to obtain error correcting codewords, and the error correcting codewords are stored into a memory page 12 of a NAND flash memory.

However, the foregoing storage manner easily causes the following problems.

1. When a compressed data block spans a plurality of error correcting codewords, a workload of metadata management cannot be ignored, and a plurality of pieces of information needs to be recorded for addressing. For example, addresses of two error correcting codewords need to be recorded for the compressed block 3

2. When a raw data block is read, some or all of the data block may be in a same error correcting codeword as another data block. Consequently, read amplification is caused, to be specific, unnecessary data also needs to be read together to complete error correcting decoding. For example, if it is intended to obtain data of the raw block 3, error correcting decoding needs to be performed on two corresponding error correcting codewords: the “compressed block 2B+compressed block 3A”, and the “compressed block 3B+compressed block 4”. However, in this process, the compressed block 2B and the compressed block 4 are further read, causing read amplification.

3. When an error correcting codeword includes some or all of a compressed data block that is deleted or updated (that is, invalid data), if the error correcting codeword still includes valid data, the invalid data in the codeword cannot be deleted until reliable recovery of the valid data is completed. Even in media that support overwriting at a same position, such as a hard disk drive (HDD), it is still not possible to release storage space immediately, resulting in wasted space and resource overheads. For example, if the raw block 3 is deleted, but because the compressed block 2B exists in one of two error correcting codes in which the raw block 3 is stored, and the compressed block 4 exists in the other, invalid data, the compressed block 3A and the compressed block 3B, in the codewords cannot be deleted until the raw blocks 2 and 4 are also deleted.

### Error Correcting Encoding

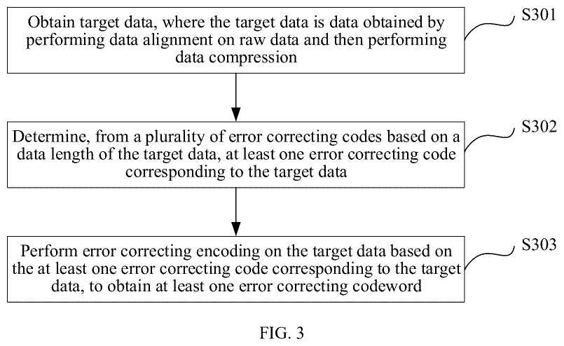

To resolve or mitigate the foregoing problems, an embodiment of this application provides an error correcting encoding method. As shown in FIG. 3, the method includes the following steps.

S301: Obtain target data, where the target data is data obtained by performing data alignment on raw data and then performing data compression.

In this embodiment, the target data is any data, provided that the target data is the data obtained by performing data alignment on the raw data and then performing data compression. Similarly, the raw data may be any type of data. For example, the target data in this embodiment may be data to be written to a storage area, or may be data to be sent. This is not limited in embodiments.

S302: Determine, from a plurality of error correcting codes based on a data length of the target data, at least one error correcting code corresponding to the target data.

At least some of the error correcting codes have different lengths.

In this embodiment, the plurality of error correcting codes may be included, and some or all of the error correcting codes may have different lengths. For example, if there are ten error correcting codes, the ten error correcting codes may have different lengths. Alternatively, two of the ten error correcting codes have a same length, and remaining error correcting codes have different lengths. Alternatively, two groups of error correcting codes in the ten error correcting codes have a same length, each group may include a plurality of error correcting codes, and remaining error correcting codes have different lengths.

In this embodiment, because data content is unpredictable, the length of the compressed target data is also unpredictable, but the length of the compressed data falls within a particular range. Therefore, in this embodiment, the plurality of error correcting codes may be preset, at least some of the error correcting codes have different lengths, and lengths of the plurality of error correcting codes may be set based on the range corresponding to the length of the compressed data.

In an implementation, in this embodiment, the lengths of the plurality of error correcting codes take a minimum length of the target data as a minimum value and increase stepwise. The minimum length of the target data may be a minimum length of the raw data after data alignment and data compression. In this embodiment, aligned data may be 4 KB, and the minimum length may be 256 B. If data alignment and data compression are performed based on another value, the minimum length may be adjusted accordingly. This is not limited in this embodiment.

In this embodiment, taking the minimum length of the target data as the minimum value and increasing stepwise means increasing the minimum length by a fixed length each time or by a fixed multiple each time. For example, the length of the error correcting code may be L+an, where L is the minimum length, a is a constant, a may be equal to L or not equal to L, a may be an integer multiple of L, n is a non-negative integer, and when n is 0, the length of the error correcting code corresponds to the minimum length. Alternatively, the length of the error correcting code may be bⁿ*L, where L is the minimum length, b is any constant greater than 1, n is a non-negative integer, and when n is 0, the length of the error correcting code corresponds to the minimum length.

The lengths of the error correcting codes take the minimum length of the target data as the minimum value and increase stepwise, so that the error correcting codes can be distributed in a stepwise manner in a data range corresponding to the length of the compressed data. When a corresponding error correcting code is determined based on the data length of the target data, the corresponding error correcting code may be selected in close proximity based on the length, so that a quantity of error correcting codes used in a process of performing error correcting encoding is reduced, and parity bits that are obtained through error correcting encoding and that are used for verification are reduced.

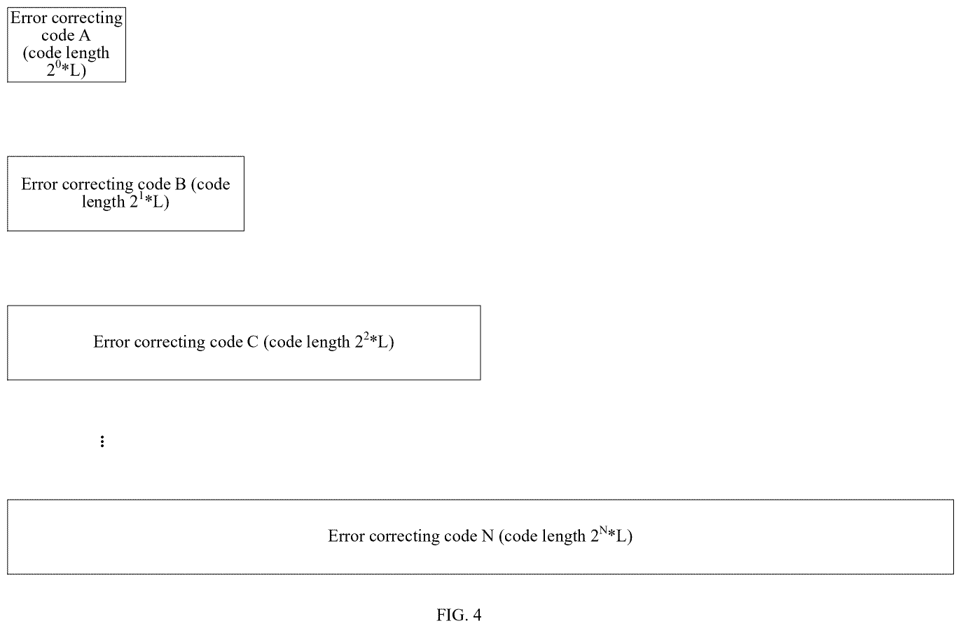

In an implementation, in this embodiment, as shown in FIG. 4, the lengths of the plurality of error correcting codes may be respectively 2ⁿ*L, where L is the minimum length of the target data, and n is a non-negative integer. In this embodiment, if the aligned data may be 4 KB, the minimum length may be 256 B. Because the data length of the target data is not greater than 4 KB, the length of the error correcting code does not need to be greater than 4 KB either. Therefore, a maximum value of nis 4, so that a maximum length is 2⁴*256B=4096B. Therefore, the lengths of the error correcting codes are respectively 2⁰*256B=256B, 2¹*256B=512B, 2²*256B=1024B, 2³*256B=2048B, and 2⁴*256B=4096B.

After the target data is obtained, an error correcting code corresponding to the target data may be selected from the plurality of error correcting codes based on the data length of the target data. One piece of target data may correspond to one or more error correcting codes. Therefore, head-to-tail splicing and segmentation do not need to be performed on the target data.

In an implementation, in this embodiment, after the target data is obtained, the target data may not match the lengths of the error correcting codes. In this case, the data length of the target data may be first supplemented, to enable the length of the target data to be equal to a multiple of the minimum length.

Specifically, in this embodiment, because the lengths of the plurality of error correcting codes may be respectively 2ⁿ*L, it may be determined that an integer multiple of the minimum length L may be equal to a sum of the lengths of the plurality of error correcting codes or equal to a length of one error correcting code. Therefore, in this embodiment, the data length of the target data may be supplemented to the integer multiple of L. Specifically, supplementation may be directly performed by using a zero vector, to ensure an extra calculation amount is not added for supplemented data.

After the supplementation, length matching may be performed on the data length of the target data and the plurality of error correcting codes having different lengths.

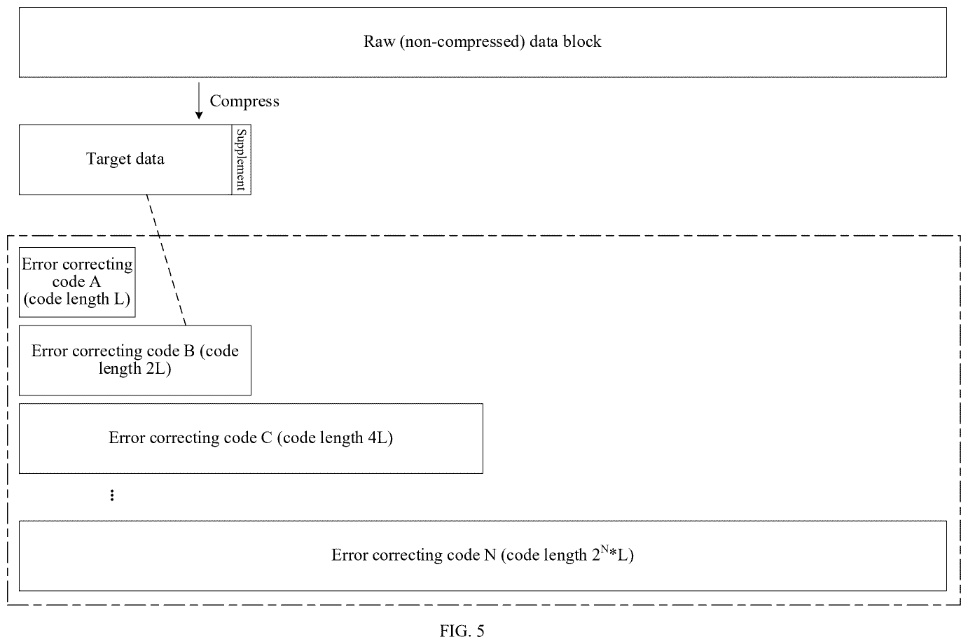

If there is an error correcting code whose length is equal to the data length, the error correcting code is determined as the error correcting code corresponding to the target data. Specifically, if a supplemented data length of the target data is equal to a length of an error correcting code, the error correcting code may be directly determined as the error correcting code corresponding to the target data. For example, as shown in FIG. 5, if a data length of target data obtained by compressing a raw data block of 4 KB is 495 B, the data length may be supplemented to 512 B, and the error correcting code B of 512 B is determined as an error correcting code corresponding to the target data. When there are a plurality of error correcting codes whose lengths are the same as the length of the target data, one of the plurality of error correcting codes having a better error correcting effect may be selected as the error correcting code of the target data based on an error correcting effect.

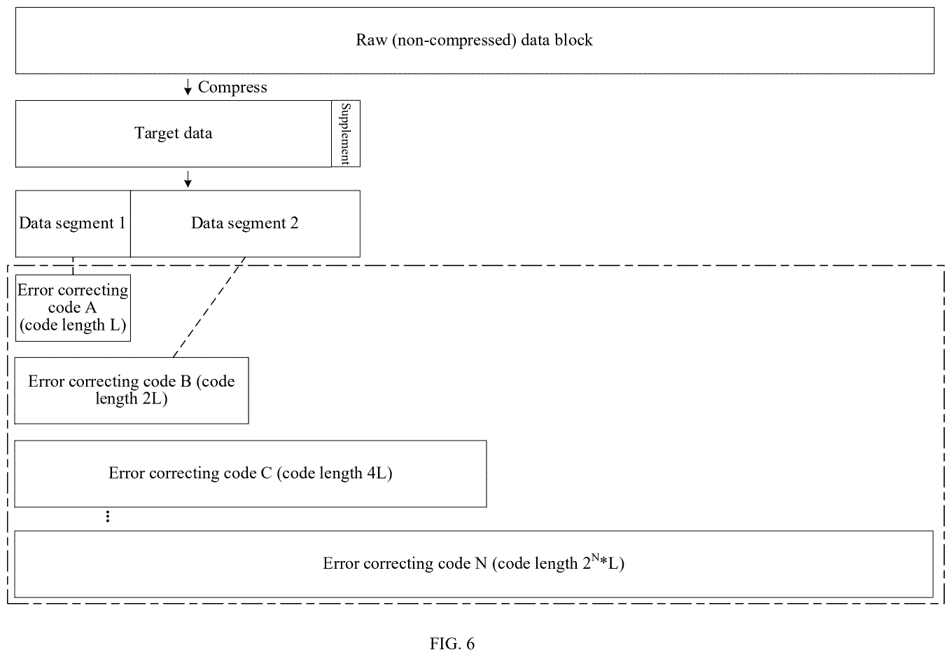

Specifically, in this embodiment, if there is no error correcting code whose length is equal to the data length, it indicates that the data length is equal to a sum of lengths of a plurality of error correcting codes. Therefore, the target data may be segmented, based on lengths of a plurality of error correcting codes, into at least two data segments whose lengths are the same as the lengths of the error correcting codes, and error correcting codes whose lengths are the same as the lengths of the data segments are determined as error correcting codes corresponding to the data segments, to determine at least two error correcting codes corresponding to the target data, where the data length is equal to a sum of lengths of the at least two error correcting codes. For example, as shown in FIG. 6, if a data length of target data obtained by compressing a raw data block of 4 KB is 695 B, the data length may be supplemented to 756 B, and the target data is segmented into a data segment of 256 B and a data segment of 512 B based on lengths of error correcting codes. An error correcting code A of 256 B is used as an error correcting code corresponding to the data segment 1 of 256 B, and an error correcting code B of 512 B is determined as an error correcting code corresponding to the data segment 2 of 512 B. The data length of 756 B=256 B+512 B. When there are a plurality of error correcting codes whose lengths are the same as a length of one data segment, one of the plurality of error correcting codes having a better error correcting effect may be selected, based on an error correcting effect, as an error correcting code corresponding to the data segment.

S303: Perform error correcting encoding on the target data based on the at least one error correcting code corresponding to the target data, to obtain at least one error correcting codeword.

In this embodiment, for a specific method of performing error correcting encoding on the target data, please refer to related technologies. Details are not described herein.

For example, the error correcting code may correspond to a check matrix. A length of the check matrix is a length of the error correcting code. The target data may be multiplied by the check matrix to obtain redundant data used for verification. The redundant data may be added to the target data as a parity bit. Because a length of the redundant data is fixed, a length of the target data with the added redundant data is also fixed.

Specifically, if the target data is segmented into a plurality of data segments, and error correcting codes whose lengths are the same as lengths of the data segments are determined as error correcting codes corresponding to the data segments, step S303 may include: respectively performing error correcting encoding on the data segments based on the error correcting codes whose lengths are the same as the lengths of the data segments, to obtain at least two error correcting codewords.

Alternatively, if the error correcting code is determined as an error correcting code whose length is the same as the length of the target data, step S303 may include: performing error correcting encoding on the target data based on the error correcting code whose length is the same as the length of the target data, to obtain an error correcting codeword. In the solutions provided in embodiments, the plurality of error correcting codes having different lengths are set, and the at least one error correcting code corresponding to the target data is determined from the plurality of error correcting codes having different lengths and based on the data length of the target data, to flexibly encode the target data. This is applicable to a data block having an indefinite data length, to avoid operations such as head-to-tail connection and segmentation, so as to implement independent error correcting code protection for each piece of compressed target data, isolate crosstalk between different target data blocks, reduce read amplification, facilitate metadata management, facilitate data recovery, and timely release storage space.

### Coder

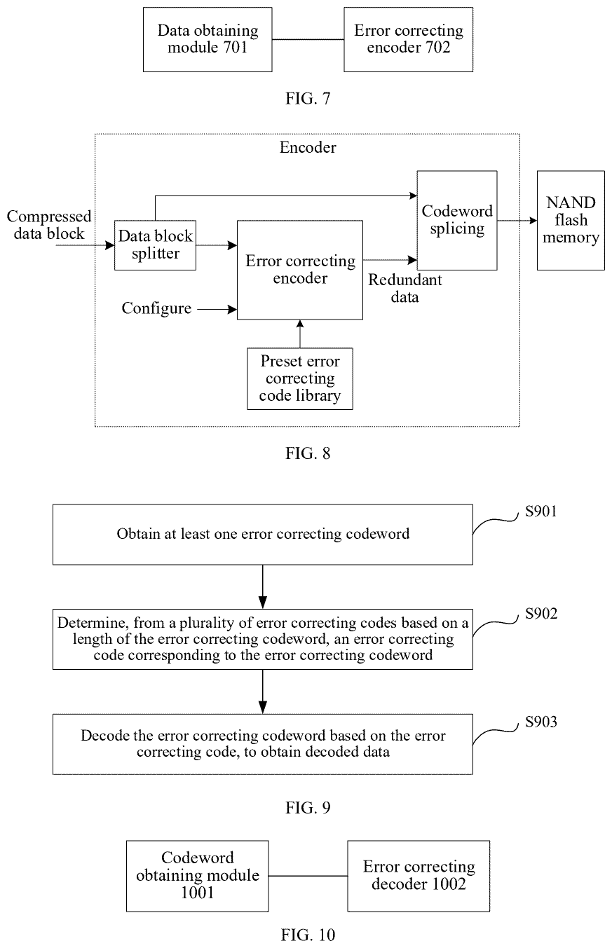

FIG. 7 is a schematic diagram of a structure of a coder according to an embodiment. As shown in the figure, the coder includes: a data obtaining module 701 and an error correcting coder 702.

The data obtaining module is configured to obtain target data, and determine, from a plurality of error correcting codes based on a data length of the target data, at least one error correcting code corresponding to the target data. The target data is data obtained by performing data alignment on raw data and then performing data compression, and at least some of the error correcting codes have different lengths.

The error correcting coder is configured to perform error correcting encoding on the target data based on the at least one error correcting code corresponding to the target data, to obtain at least one error correcting codeword.

In an implementation, in this embodiment, lengths of the plurality of error correcting codes take a minimum length of the target data as a minimum value and increase stepwise.

In an implementation, in this embodiment, the lengths of the plurality of error correcting codes are respectively 2ⁿ*L, where L is the minimum length of the target data, and n is a non-negative integer.

In an implementation, in this embodiment, the data obtaining module is specifically a data segmentation module, configured to: supplement the data length of the target data, to enable the length of the target data to be equal to a multiple of the minimum length; perform length matching on the data length of the target data and the plurality of error correcting codes; and if there is an error correcting code whose length is equal to the data length, determine the error correcting code as an error correcting code corresponding to the target data.

In an implementation, in this embodiment, the data segmentation module is further configured to: if there is no error correcting code whose length is equal to the data length, segment, based on the lengths of the plurality of error correcting codes, the target data into at least two data segments whose lengths are the same as the lengths of the error correcting codes, and determine error correcting codes whose lengths are the same as the lengths of the data segments as error correcting codes corresponding to the data segments, to determine at least two error correcting codes corresponding to the target data. The data length is equal to a sum of lengths of the at least two error correcting codes. The error correcting coder is further configured to: obtain, from a preset error correcting code library, error correcting codes whose lengths are the same as the lengths of the data segments, and respectively perform error correcting encoding on the data segments based on the obtained error correcting codes, to obtain the at least two error correcting codewords.

In an implementation, in this embodiment, sizes of base matrixes of redundancy check matrixes respectively corresponding to the plurality of error correcting codes are the same, and the error correcting coder is configured to perform parallel error correcting encoding based on a length of the base matrix as a unit. Therefore, coding corresponding to the lengths of the plurality of error correcting codes may be implemented by using one error correcting coder. Similarly, parallel decoding may also be performed by a decoder based on the length of the base matrix as a unit, so that a set of coding hardware and decoding hardware can flexibly adapt to error correcting codes having different lengths.

Specifically, generally, a redundancy check matrix may be segmented into two sub-matrixes. One is a non-zero matrix, and the other is an all-zero matrix. The non-zero matrix is usually a unit matrix or is obtained by converting the unit matrix. Therefore, the non-zero matrix may be referred to as a base matrix.

For example, a redundancy check matrix H may be:

$$H = [ \begin{matrix}1 & 0 & 0 & 0 & 0 & 0 & 0 & 1 & 1 & 0 & 0 & 0 & 0 & 0 & 0 & 0 \\ 0 & 1 & 0 & 0 & 1 & 0 & 0 & 0 & 0 & 1 & 0 & 0 & 0 & 0 & 0 & 0 \\ 0 & 0 & 1 & 0 & 0 & 1 & 0 & 0 & 0 & 0 & 1 & 0 & 0 & 0 & 0 & 0 \\ 0 & 0 & 0 & 1 & 0 & 0 & 0 & 0 & 0 & 0 & 0 & 1 & 0 & 0 & 0 & 0 \\ 0 & 0 & 1 & 0 & 0 & 0 & 1 & 0 & 0 & 0 & 1 & 0 & 0 & 0 & 0 & 1 \\ 0 & 0 & 0 & 1 & 1 & 0 & 0 & 0 & 0 & 0 & 0 & 1 & 1 & 0 & 0 & 0 \\ 1 & 0 & 0 & 0 & 0 & 1 & 0 & 0 & 1 & 0 & 0 & 0 & 0 & 1 & 0 & 0 \\ 0 & 1 & 0 & 0 & 0 & 0 & 1 & 0 & 0 & 1 & 0 & 0 & 0 & 0 & 1 & 0\end{matrix} ]$$

The redundancy check matrix H includes eight sub-matrixes. The 4^{th} sub-matrix in the 1^{st} row is an all-zero matrix, and remaining seven sub-matrixes are all non-zero matrixes.

A length of the base matrix is 4, and the error correcting coder may perform parallel error correcting encoding based on the length of the base matrix as a unit, that is, perform parallel error correcting encoding by using 4 as a length unit. Certainly, an example in which the length of the base matrix is 4 is merely used for description in the foregoing. In another implementation, the length of the base matrix may be equal to the minimum length of the target data. To be specific, when data is aligned into 4 KB, the minimum length of the target data may be 256, and the length of the base matrix may also be 256. In other words, an error correcting code having a minimum length is the base matrix.

FIG. 8 is a schematic diagram of a structure of a coder. As shown in the figure, the coder includes: a data segmentation module, an error correcting coder, a preset error correcting code library, and a codeword splicing module.

As shown in FIG. 8, compressed target data may be input to the data segmentation module, and the data segmentation module supplements a data length of the target data to a multiple of a minimum length of the target data.

If the data length is equal to a length of an error correcting code, the data segmentation module outputs the target data, to determine the error correcting code as an error correcting code corresponding to the target data. If the data length is not equal to a length of any error correcting code, it indicates that the data length is equal to a sum of lengths of at least two error correcting codes. In this case, the target data is segmented based on lengths of a plurality of preset error correcting codes. The target data is segmented into at least two data segments whose lengths are the same as length of the error correcting code, to obtain at least two data segments, and a data length of the data segment is equal to a length of an error correcting code.

The error correcting coder may pre-input configuration information. The configuration information indicates a parameter setting of a currently selected error correcting code corresponding to the length of the data segment, for example, a setting used for coding, such as a length of the error correcting code and whether “shorten” is needed.

The error correcting coder may obtain corresponding error correcting codes from the preset error correcting code library based on a data length of data (the target data or the data segments obtained through segmentation) output by the data segmentation module, perform error correcting encoding, and output redundant data.

The redundant data may be used as a parity bit, and is added to the data (the target data or the data segments) output by the data segmentation module to obtain error correcting codewords. The error correcting codewords may be input to the codeword splicing module, to splice one or more error correcting codewords to obtain data whose size is the same as a size of a NAND memory page, and the data may be stored into the NAND memory page.

It should be noted that details of a coding method are described in detail in the foregoing embodiments. For a specific process, refer to the descriptions in the foregoing coding method embodiments. Details are not described herein again.

### Error Correcting Decoding

Another embodiment of this application further provides an error correcting decoding method. As shown in FIG. 9, the method includes the following steps.

S901: Obtain at least one error correcting codeword.

In this embodiment, the error correcting codeword may be read from a storage area, or may be received. This is not limited in embodiments.

S902: Determine, from a plurality of error correcting codes based on a length of the error correcting codeword, an error correcting code corresponding to the error correcting codeword.

At least some of the error correcting codes have different lengths.

In this embodiment, during coding, at least some of the plurality of used error correcting codes have different lengths, so that obtained error correcting codewords have different lengths. Therefore, corresponding error correcting codes may be determined from the plurality of error correcting codes based on the lengths of the error correcting codewords. If there are error correcting codes having the same length, an error correcting code having a better decoding effect may be selected as the error correcting code corresponding to the error correcting codeword.

S903: Decode the error correcting codeword based on the error correcting code, to obtain decoded data.

If target data is supplemented during coding, during decoding, supplemented data may be assigned a known value such as zero, so that an amount of data that needs to be calculated during decoding is reduced, to facilitate decoding and accelerate convergence.

### Decoder

As shown in FIG. 10, an embodiment provides a decoder. As shown in the figure, the decoder includes:
a codeword obtaining module 1001, configured to obtain at least one error correcting codeword; and
an error correcting decoder 1002, configured to determine, from a plurality of error correcting codes based on a length of the error correcting codeword, an error correcting code corresponding to the error correcting codeword, and decode the error correcting codeword based on the error correcting code, to obtain decoded data, where at least some of the error correcting codes have different lengths.

In addition, in this embodiment, sizes of base matrixes of redundancy check matrixes respectively corresponding to the plurality of error correcting codes are the same, and the error correcting decoder is configured to perform parallel error correcting decoding based on a length of the base matrix as a unit. Specifically, if the base matrix is a matrix of PQ rows and PQ columns, a parallelism degree is PQ, in other words, parallel decoding of a PQ length may be processed each time. If the length of the error correcting codeword that needs to be decoded is small, a plurality of error correcting codewords may be decoded in parallel. For example, if lengths of two error correcting codewords are both 2 KB, and a maximum error correcting code length that can be supported by the error correcting decoder is 4 KB, the two error correcting codewords may be simultaneously decoded.

In addition, it should be noted that although the error correcting decoder may perform parallel decoding, a device configured to perform decoding needs to temporarily store data during decoding. Therefore, the device configured to perform decoding needs to be set according to a maximum decoding amount.

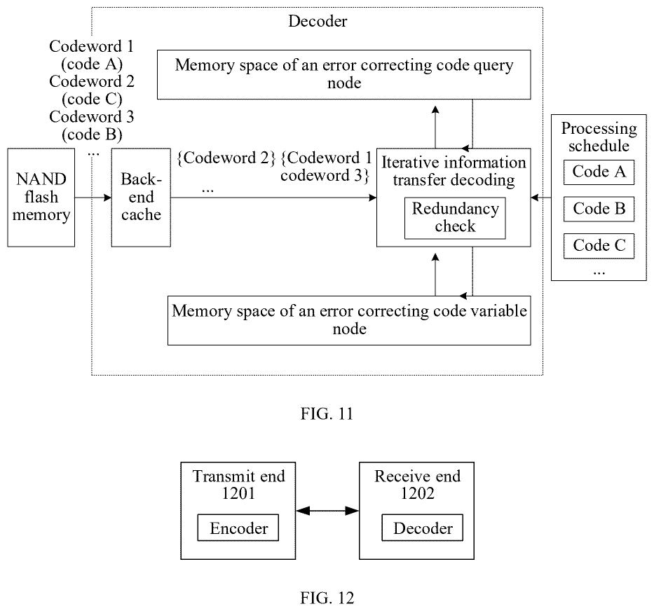

FIG. 11 is a schematic diagram of a structure of another decoder. As shown in the figure, the decoder includes: a back-end storage module, an error correcting decoding module, a processing schedule storage module, a memory space of an error correcting code query node, and a memory space of an error correcting code variable node.

The back-end storage module may be configured to read an error correcting codeword from a NAND flash memory and store the error correcting codeword, and may transmit a plurality of error correcting codewords 1, 2, 3, and the like out of order to the error correcting decoding module. The error correcting decoding module may specifically use an iterative information transfer decoding manner. The error correcting decoding module may perform decoding based on decoding content, for example, codes A, B, and C, recorded in a decoding schedule stored in the processing schedule storage module, may specifically perform error correcting code query from the memory space of the error correcting code query node, determine an error correcting code corresponding to the error correcting codeword, may perform parallel decoding in a time division multiplexing manner, and store a variable generated during decoding into the memory space of the error correcting code variable node.

Therefore, the memory space of the error correcting code query node and the memory space of the error correcting code variable node may be set based on a maximum decoding amount, and the error correcting decoding module may be set based on a length of a base matrix.

For example, in FIG. 11, a plurality of error correcting codewords 1, 2, and 3 may be read and cached to a back-end cache module. The codewords 1 and 3 are respectively 2 KB, and the codeword 2 is 4 KB. In this case, the codewords 1 and 3 may be simultaneously decoded, and the codeword 2 is independently decoded. After decoding, splicing and combination may be performed based on preset fields to obtain the codes A, B, and C. Therefore, a delay of a decoding process can be reduced, and resource utilization can be improved.

### Communication System

It should be noted that the foregoing error correcting encoding and error correcting decoding solutions may also be applied to the communication field. Therefore, refer to FIG. 12. Another embodiment of this application provides a communication system, including a transmit end 1201 and a receive end 1202. The transmit end may include the foregoing coder, configured to perform error correcting encoding on to-be-sent data, and the receive end may include the foregoing decoder, configured to perform error correcting decoding on received data.

It should be noted that user information (including, but not limited to, user equipment information, user personal information, and the like) and data (including, but not limited to, data for analysis, stored data, displayed data, and the like) in this application are all information and data authorized by a user or fully authorized by all parties. Collection, use, and processing of related data need to comply with relevant laws, regulations and standards of relevant countries and regions. A corresponding operation entry is provided for the user to select to authorize or reject.

It should be noted that based on an implementation need, each component/step described in embodiments of this application may be divided into more components/steps, or two or more components/steps or some operations of the components/steps may be combined into a new component/step, to achieve an objective of embodiments of this application.

The foregoing method according to embodiments of this application may be implemented in hardware, firmware, or implemented as software or computer code that may be stored in a recording medium (such as a CD ROM, a RAM, a floppy disk, a hard disk drive, or a magneto-optical disk), or implemented as computer code that is originally stored in a remote recording medium or a non-transitory machine readable medium and that is to be stored in a local recording medium and that is downloaded by using a network, so that the method described herein may be processed by such software stored on a recording medium using a general-purpose computer, a dedicated processor, or programmable or dedicated hardware (such as an ASIC or an FPGA). It may be understood that the computer, the processor, a microprocessor controller, or the programmable hardware includes a storage component (such as a RAM, a ROM, or a flash memory) that can store or receive software or computer code. When the software or the computer code is accessed and executed by the computer, the processor, or the hardware, the method described herein is implemented. In addition, when the general-purpose computer accesses code used for implementing the method herein, execution of the code converts the general-purpose computer into a dedicated computer used for performing the method herein.

A person of ordinary skill in the art may be aware that, in combination with examples described in embodiments disclosed in this specification, units and method steps can be implemented by electronic hardware or a combination of computer software and electronic hardware. Whether the functions are executed in a mode of hardware or software depends on particular applications and design constraint conditions of the technical solutions. A person skilled in the art may use different methods to implement the described functions for each particular application, but it should not be considered that the implementation goes beyond the scope of embodiments of this application.

The foregoing implementations are merely used for describing embodiments of this application, but are not intended to limit embodiments of this application. A person of ordinary skill in the related art may make various changes and variations without departing from the spirit and scope of embodiments of this application. Therefore, all equivalent technical solutions fall within the scope of embodiments of this application. The patent protection scope of embodiments of this application should be limited by the claims.

1. An error correcting encoding method, comprising:
obtaining target data, wherein the target data is data obtained by performing data alignment on raw data and then performing data compression;
determining, from a plurality of error correcting codes based on a data length of the target data, at least one error correcting code corresponding to the target data, wherein at least some of the error correcting codes have different lengths; and
performing error correcting encoding on the target data based on the at least one error correcting code corresponding to the target data, to obtain at least one error correcting codeword.

2. The method according to claim 1, wherein lengths of the plurality of error correcting codes take a minimum length of the target data as a minimum value and increase stepwise.

3. The method according to claim 2, wherein the lengths of the plurality of error correcting codes are respectively 2ⁿ*L, wherein L is the minimum length of the target data, and n is a non-negative integer.

4. The method according to claim 3, wherein the determining, from a plurality of error correcting codes based on a data length of the target data, at least one error correcting code corresponding to the target data comprises:
supplementing the data length of the target data, to enable a length of the target data to be equal to a multiple of the minimum length;
performing length matching on the data length of the target data and the plurality of error correcting codes; and
if there is an error correcting code whose length is equal to the data length, determining the error correcting code as an error correcting code corresponding to the target data.

5. The method according to claim 4, wherein the determining, from a plurality of error correcting codes based on a data length of the target data, at least one error correcting code corresponding to the target data further comprises:
if there is no error correcting code whose length is equal to the data length, segmenting, based on the lengths of the plurality of error correcting codes, the target data into at least two data segments whose lengths are the same as the lengths of the error correcting codes, and determining error correcting codes whose lengths are the same as the lengths of the data segments as error correcting codes corresponding to the data segments, to determine at least two error correcting codes corresponding to the target data, wherein the data length is equal to a sum of lengths of the at least two error correcting codes; and
the performing error correcting encoding on the target data based on the at least one error correcting code corresponding to the target data, to obtain at least one error correcting codeword comprises:
respectively performing error correcting encoding on the data segments based on the error correcting codes whose lengths are the same as the lengths of the data segments, to obtain at least two error correcting codewords.

6. A coder, comprising: a receiver, a processor and an error correcting coder, wherein
the receiver is configured to obtain target data;
the processor is configured to determine, from a plurality of error correcting codes based on a data length of the target data, at least one error correcting code corresponding to the target data, the target data is data obtained by performing data alignment on raw data and then performing data compression, and at least some of the error correcting codes have different lengths; and
the error correcting coder is configured to perform error correcting encoding on the target data based on the at least one error correcting code corresponding to the target data, to obtain at least one error correcting codeword.

7. The coder according to claim 6, wherein lengths of the plurality of error correcting codes are respectively 2ⁿ*L, wherein L is a minimum length of the target data, and n is a non-negative integer.

8. The coder according to claim 7, wherein the processor is further configured to: supplement the data length of the target data, to enable a length of the target data to be equal to a multiple of the minimum length; perform length matching on the data length of the target data and the plurality of error correcting codes; and if there is an error correcting code whose length is equal to the data length, determine the error correcting code as an error correcting code corresponding to the target data.

9. The coder according to claim 6, wherein sizes of base matrixes of redundancy check matrixes respectively corresponding to the plurality of error correcting codes are the same, and the error correcting coder is configured to perform parallel error correcting encoding based on a length of the base matrix as a unit.

10. An error correcting decoding method, comprising:
obtaining at least one error correcting codeword;
determining, from a plurality of error correcting codes based on a length of the error correcting codeword, an error correcting code corresponding to the error correcting codeword, wherein at least some of the error correcting codes have different lengths; and
decoding the error correcting codeword based on the error correcting code, to obtain decoded data.

11. A decoder, comprising:
a processor, a receiver coupled to the processor, a memory coupled to the processor, and a transmitter coupled to the processor, wherein the processor, receiver, memory, and transmitter are configured to perform the error correcting decoding method according to claim 10.

12. A storage control chip, comprising the coder according to claim 6.

13. A solid state disk, comprising:
the storage control chip according to claim 12; and
at least one flash memory chip, wherein the flash memory chip comprises at least one memory block, each memory block comprises a plurality of memory pages, and each memory page comprises a plurality of storage units.

14. A communication system, comprising a transmit end and a receive end, wherein the transmit end comprises the coder according to claim 6.

15. A storage control chip, comprising the decoder according to claim 11.

16. The communication system according to claim 14, wherein the receive end comprises a decoder, wherein the decoder comprising:
a processor, a receiver coupled to the processor, a memory coupled to the processor, and a transmitter coupled to the processor, wherein the processor, receiver, memory, and transmitter are configured to:
obtain at least one error correcting codeword;
determine, from a plurality of error correcting codes based on a length of the error correcting codeword, an error correcting code corresponding to the error correcting codeword, wherein at least some of the error correcting codes have different lengths; and
decode the error correcting codeword based on the error correcting code, to obtain decoded data.

17. The coder according to claim 6, wherein lengths of the plurality of error correcting codes take a minimum length of the target data as a minimum value and increase stepwise.

18. The coder according to claim 6, wherein the processor is further configured to:
if there is no error correcting code whose length is equal to the data length, segment, based on the lengths of the plurality of error correcting codes, the target data into at least two data segments whose lengths are the same as the lengths of the error correcting codes, and determine error correcting codes whose lengths are the same as the lengths of the data segments as error correcting codes corresponding to the data segments, to determine at least two error correcting codes corresponding to the target data, wherein the data length is equal to a sum of lengths of the at least two error correcting codes; and
the error correcting coder is specifically configured to:
respectively perform error correcting encoding on the data segments based on the error correcting codes whose lengths are the same as the lengths of the data segments, to obtain at least two error correcting codewords.

19. A non-transitory computer-readable storage medium storing computer instructions, wherein the computer instructions are used to cause a computer to perform the error correcting encoding method according to claim 1.

20. A non-transitory computer-readable storage medium storing computer instructions, wherein the computer instructions are used to cause a computer to perform the error correcting decoding method according to claim 10.
